(19) United States
(12) Patent Application Publication
(10) Pub. No.: US 2012/0153964 A1
(43) Pub. Date: Jun. 21, 2012

(54) SYSTEM AND METHOD FOR DETECTING ISOLATION BARRIER BREAKDOWN

(75) Inventors: Baoxing CHEN, Westford, MA (US); Adam GLIBBERY, Hants (GB)

(73) Assignee: ANALOG DEVICES, INC., Norwood, MA (US)

(21) Appl. No.: 12/974,198

(22) Filed: Dec. 21, 2010

(51) Int. Cl. G01R 31/12; G01R 31/06

(52) U.S. Cl. 324/547; 324/548

(57) ABSTRACT

A circuit system includes a first circuit for receiving an input signal, a second circuit for interfacing with a user, a signal path connecting the first circuit to the second circuit, the signal path including a first isolator and a second isolator serially connected to the first isolator, and a capacitance detector that detects a change in a combined capacitance of the first and second isolators as an indicator of a breakdown of one of the first and second isolators.

### FIELD OF THE INVENTION

The present invention is generally directed to systems and methods of detecting breakdowns in isolators that isolate user interface circuits from drive circuits. In particular, the present invention is directed to systems and methods that may detect a potential breakdown of an isolation barrier including isolators by monitoring changes in the capacitance of the isolators.

### BACKGROUND INFORMATION

For safety reasons, a user interface circuit may be isolated from a drive circuit by an isolation barrier that may include isolators so that currents may not directly flow from the drive circuit to the user interface circuit. Exemplary isolators may include transformers and/or capacitors that may allow the passage of voltage signals but not the passage of direct currents.

FIG. 1 illustrates a system 100 including an isolator 20 that may isolate a drive circuit 18 from an interface circuit 24. The system 100 may include an input die 12 and an interface die 14. A drive circuit 18 may be fabricated on the input die 12, and an interface circuit 24 may be fabricated on the interface die 14. A signal path 22 may connect the modulator die including the drive circuit 18 to the interface die 14 including the interface circuit 24. The signal path 22 may include an isolator 20 that may isolate the interface circuit 24 from direct currents from the drive circuit 18 and also isolate the drive circuit from the interface circuit. In practice, the isolator 20 may be a transformer or a capacitor.

In operation, an input signal 16 such as a current signal may drive the drive circuit 18. The drive circuit 18 may output a voltage signal to the signal path 22 that includes the isolator 20. The isolator 20 may transfer the voltage signal from an input (I) to an output (O) of the isolator 20 and at the same time, isolate the output from the input. The output from the isolator may be provided to the interface circuit 24 which may generate a further output to the user 26. As such, a user who receives the output 26 may be protected from power surges in the drive circuit 18. FIG. 1 illustrates only one signal path 22. However, in practice, there may be a number of signal paths such as data signal paths and clock signal paths between the drive circuit 18 and the interface circuit 24. Therefore, each of the signal paths may include an isolator for isolating interface circuit 24 from the drive circuit 18.

With the trend of smaller circuit dies for consumer electronics, the isolators also may become smaller. A smaller isolator may increase the chance of an isolator breakdown or a short circuit from an isolator input to an output of the isolator. For safety reasons, it may be desirable that users be pre-warned of any potential isolator breakdowns before the breakdowns actually occur. However, with current art of using a single isolator per signal path, it may be difficult to detect a breakdown of the single isolator prior to its occurrence. On the other hand, a detection of the breakdown after its occurrence may not help protecting the user from leakage currents that may have already flown from the drive circuit to the interface circuit.

Therefore, there is a need for systems and methods that may detect potential isolator breakdowns prior to their occurrences and warn the user of the same.

### BRIEF DESCRIPTION OF THE DRAWINGS

FIG. 1 illustrates a system that uses a single isolator to isolate a drive circuit from an interface circuit.

FIG. 2 illustrates a system that may detect potential isolation barrier breakdowns according to an exemplary embodiment of the present invention.

FIG. 3 illustrates a system that may detect potential isolation barrier breakdowns using a capacitance-to-voltage converter according to an exemplary embodiment of the present invention.

FIG. 4 illustrates a differential capacitance-to-voltage converter according to an exemplary embodiment of the present invention.

FIG. 5 illustrates a system that may detect isolation barrier breakdowns in multiple signal paths according to an exemplary embodiment of the present invention.

### DETAILED DESCRIPTION OF EXAMPLE EMBODIMENTS

Embodiments of the present invention may be directed to a system that may include a first circuit for receiving an input signal, a second circuit for interfacing with a user, a signal path connecting the first circuit to the second circuit, the signal path including a first isolator and a second isolator serially connected to the first isolator, and a capacitance detector that detects a change in a combined capacitance of the first and second isolators as an indicator of a breakdown of one of the first and second isolators.

Embodiments of the present invention may provide a system that may include a plurality of serially-connected isolators as an isolation barrier for isolating a second circuit from a first circuit, a capacitance detector for monitoring changes in the capacitance of the serially-connected isolators caused by an isolator breakdown, and a status logic circuit that may generate a notice to the user in response to the changes in capacitance of the serially-connected isolators caused by a capacitor breakdown. In the event that one of the serially-connected isolators breaks down, the second circuit may still be isolated from the first circuit. However, the isolation barrier between the first and the second circuit may become vulnerable for a subsequent complete breakdown of the isolation barrier. Therefore, a detection of the breakdown of one isolator out of a number of serially-connected isolators may be the triggering event to notify a user of a potential breach of the isolation barrier.

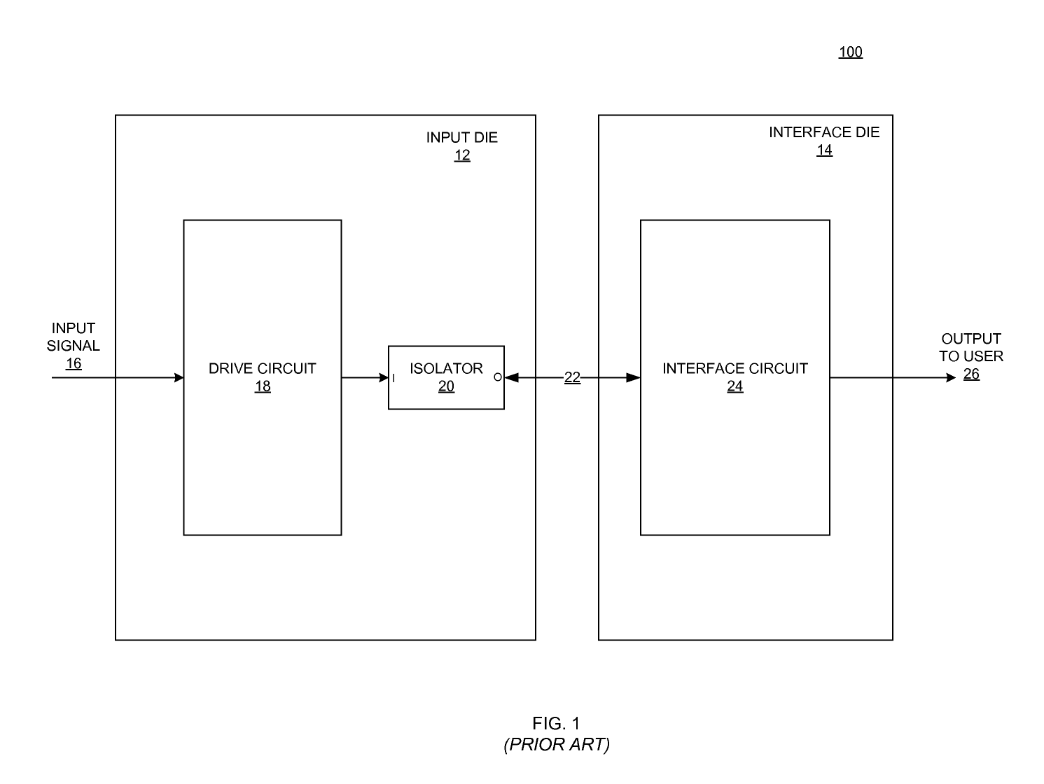

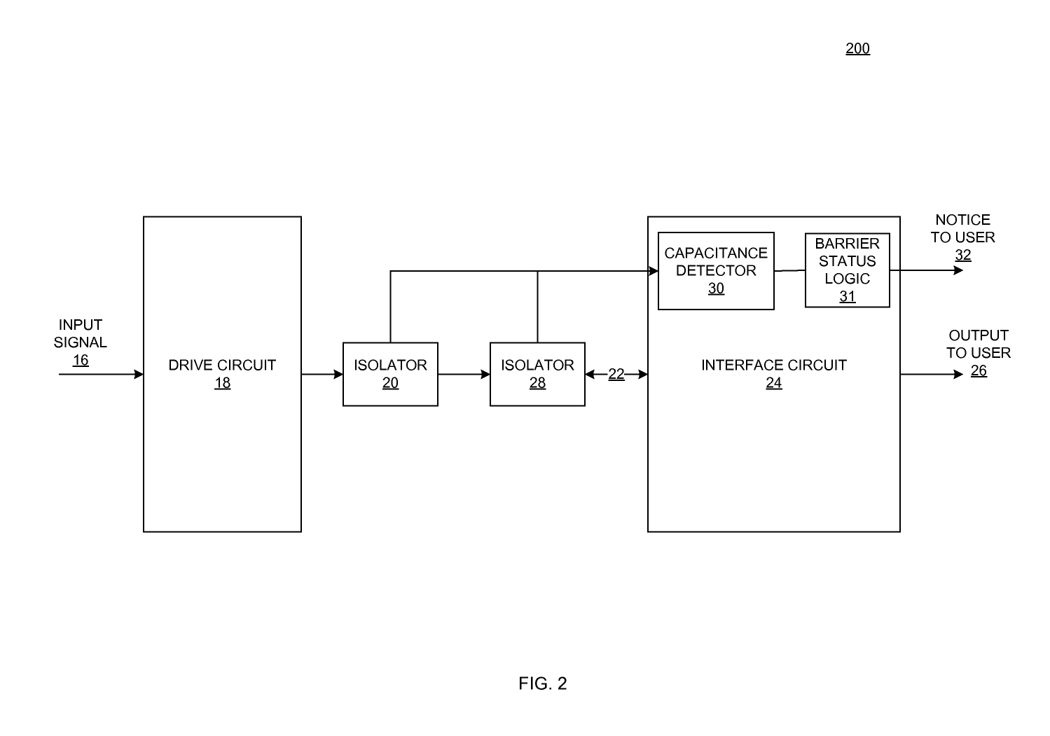

In the event that one out of the serially-connected isolators breaks down, the combined capacitance for all of the serially-connected isolators may change. Therefore, the breakdown of one of the serially-connected isolators may be detected by monitoring the capacitance change of the serially-connected isolators. FIG. 2 illustrates a system 200 that may detect potential isolation barrier breakdowns according to an exemplary embodiment of the present invention. The system 200 may, like the system 100 as illustrated in FIG. 1, include a drive circuit 18 and an interface circuit 24 connected to the drive circuit 18 via a signal path 22. In the signal path 22, two isolators 20, 28 may be serially connected to form an isolation barrier. A capacitance detector 30 may be formed on the interface circuit die. The capacitance detector 30 may be capable of detecting a capacitance change caused by the breakdown of one of the isolators 20 and 28. A barrier status logic circuit 31 may be coupled to an output of the capacitance detector and determine whether a capacitance change indicates a breakdown of one of the isolators. Upon determining such a breakdown, the barrier status logic circuit 31 may generate a notice 32 to the user to warn the user of the isolator breakdown or a weakening of the isolation barrier.

In one embodiment, the two serially-connected isolators 20, 28 may be two back-to-back connected transformers. The two transformers may include substantially identical characteristics. Thus, each of the two transformers may include a first coil of a first number of windings and a second coil of a second number of windings. The first coil of the first isolator 20 may be connected to the drive circuit, the second coil of the first isolator 20 may be connected to the second coil of the second isolator 28, and the first coil of the second isolator 28 may be capacitively connected to the interface circuit via a capacitor. In an alternative embodiment, the two serially-connected isolators 20, 28 may be two back-to-back connected capacitors. The two capacitors may include substantially identical characteristics.

In operation, an input signal 16 may drive the drive circuit 18 to produce an output signal of the drive circuit 18. The output signal of the drive circuit 18 may be fed via the signal path 22 to the first isolator 20 and then to the second isolator 28 and finally to the interface circuit 24. The interface circuit 24 may then generate an output 26 to the user. The capacitance detector 30 may continuously monitor a combined capacitance of the serially-connected isolators 20, 28. Thus, assuming the capacitances of isolators 20, 28 are Ci1 and Ci2, respective, the combined capacitance may be Ci=Ci1*Ci2/(Ci1+Ci2). During normal operation, both isolators 20, 28 may work normally, and their capacitance may not change much. However, in the event that one of the isolators 20, 28 breaks down (or is short-circuited), the combined capacitance Ci of the serially-connected isolators 20, 28 may increase. The barrier status logic may detect the capacitance increase and generate a notice to the user based on the amount of capacitance change.

Different types of capacitance detectors may be used to sense capacitance changes. For example, in one embodiment, the capacitance detector 30 may include a capacitance-to-voltage converter so that the capacitance changes may be measured in terms of voltage changes. One issue with measuring the capacitance may be that the capacitance of the isolators may be measured while the isolators are operating on the signal path. Thus, the capacitance of isolators may not be measured by directly applying a known excitation. Instead, the capacitance of isolators is measured while the input excitation may vary. U.S. Pat. No. 7,235,983 (the '983 patent) (the content of which is incorporated by reference in its entirety) by the assignee of the present invention illustrates a number of capacitance-to-voltage converters.

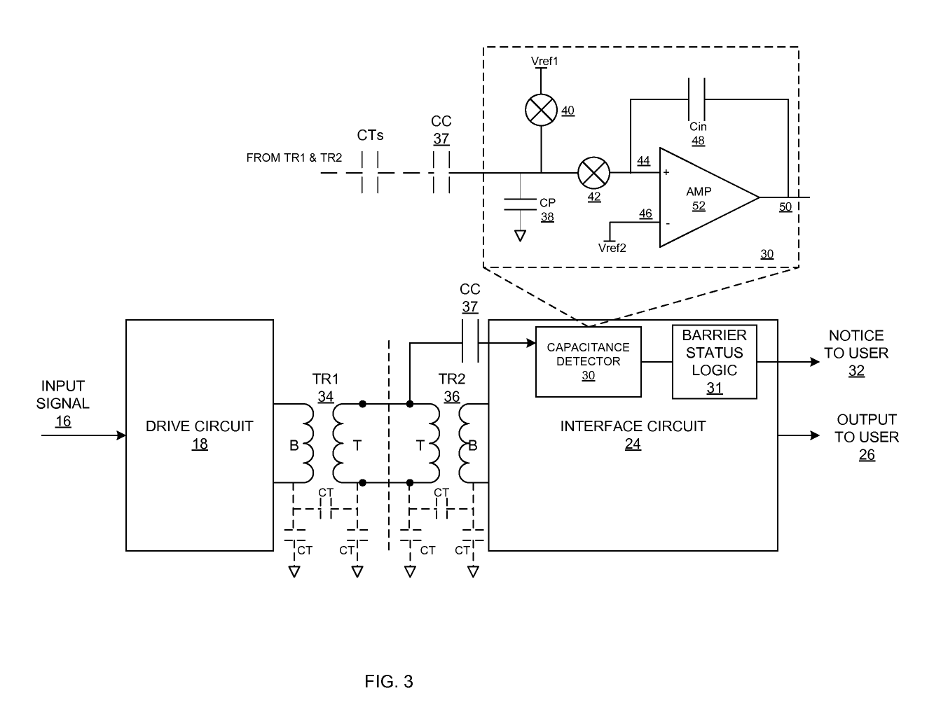

FIG. 3 illustrates a system that may detect potential isolator breakdowns using a capacitance-to-voltage converter according to an exemplary embodiment of the present invention. In this exemplary embodiment, two back-to-back connected transformers 34, 36 may be used as isolators to form an isolation barrier. Each of the transformers 34, 36 may include a bottom coil (B) and a top coil (T), in which the bottom coil may include a first number of windings and the top coil may include a second number of windings. For example, the winding of the top coil may be greater than or equal to the winding of the bottom coil. The bottom coil of the first transformer 34 may be coupled to the drive circuit 18, the top coil of the first transformer 34 may be coupled to the top coil of the second transformer 36, and the bottom coil of the second transformer may be coupled to the interface circuit 24. Further, each of the transformers 34, 36 may include parasitic capacitance (CT) that may constitute the capacitance of transformers 34, 36. In one exemplary embodiment, the serially-connected transformers 34, 36 may be capacitively connected to the capacitance detector 30. Thus, the connection between the second transformer 36 to the capacitance detector 30 may include a capacitor (CC) 37. The capacitor 37 may isolate the top coil of the second transformer 36 from the bottom coil of the second transformer 36.

The exemplary capacitance detector 30 (as illustrated in the dashed box) may include an amplifier 52 that may further include a summing node 44, a reference node 46, and an output node 50. The capacitance detector 30 also may include an integrating capacitor (Cin) 48 coupled between the summing node 44 and the output 50 of the amplifier 50 while the reference node 46 of the amplifier 52 may be coupled to a reference voltage Vref2. Another reference voltage Vref1 may be coupled to the summing node 44 via a first phased switch 40 and a second phased switch 42. A second capacitor (CP) 38 may be coupled between the ground and the summing node 44 via the second switch 42. A first capacitive load CTs (i.e., the combined parasitic capacitance of the first and second transformers) whose capacitance is to be sensed and a second capacitive load CC of the capacitor 37 are also illustrated in dashed lines.

In operation, the first phased switch 40 and the second phased switch 42 may operate according to two phases of clock. During the first phase, the first switch 40 may be engaged (or closed) and the second switch 42 may be disengaged (or open), and during the second phase, the first switch 40 may be disengaged (or open) and the second switch 42 may be engaged (or closed). Thus, during the first phase, the reference voltage Vref1 may charge the combined capacitor of CP 38, CTs, and CC 37. Since CP are parallelly connected to the serially-connected CTs and CC, the capacitance of the combined CP, CTs, and CC may be CP+(CTs*CC/(CTs+CC)). During the second phase, the charged CP, CTs, and CC having a charge of Vref1 may be switched to the summing node 44 via the second switch 42. When Vref1 at the summing node 44 is different from Vref2 at the reference node, the amplifier 52 may generate a current of (Vref1−Vref2)*(CP+CTs*CC/(CTs+CC)) to minimize the difference. The current may be integrated through the integrating capacitor Cin 48 to transfer a current to the output node 50 and thus may produce an output voltage which may represent (CP+CTs*CC/(CTs+CC)).

During normal operation when both transformers 34, 36 act as isolators, the output voltage at the output node 50 of the amplifier 52 may maintain a consistent pattern that represents the normal parasitic capacitance CTs from the transformers 34, 36. However, when any one of the transformers 34, 36 breaks down, the broken down transformer may be shorted. As such, the sense capacitance may be primarily CC of the capacitor 37. Thus, the sensed capacitance may increase because the loss (or increase of the combined capacitance) of CT in the serially-connected parasitic capacitance. Thus, the output voltage at the output node 50 also may be deviated from its normal pattern. For example, the output voltage at the output node 50 may be increased because of the breakdown. Based on this voltage increase, a user may be notified by the barrier status logic 31 of a potential isolation barrier breakdown before a total breakdown takes place.

In practice, since CTs represents parasitic capacitance, its value may not be very stable and may vary within a range. The variability of CTs may be taken account for by the barrier status logic 31 in determining whether a voltage change at the output node 50 indeed represents a breakdown of a transformer. In one embodiment, the sensitivity of the output voltage may be controlled by the capacitance values of CC and CP. Thus, when CC or CP is chosen small relative to CTs, the output voltage at the output node 50 may be more sensitive to changes of CTs. However, when CC or CP is chosen large relative to CTs, the output voltage at the output node 50 may be less sensitive to changes to CTs. In one preferred embodiment, CC and CP may be chosen in the substantially same range of CTs. In another preferred embodiment, CC and CP may be chosen such that a breakdown of one of the isolators may represent about 10% of voltage change in the voltage output of the capacitance detector 30.

FIG. 2 illustrates an exemplary embodiment where the excitation (Vref1) to the sensed parasitic capacitance is from the top coil of the second transformer 36. However, the present invention is not limited to this particular embodiment. The excitation may be applied from other points of the isolators. For example, the excitation may be applied from the bottom coil of the second transformer 36.

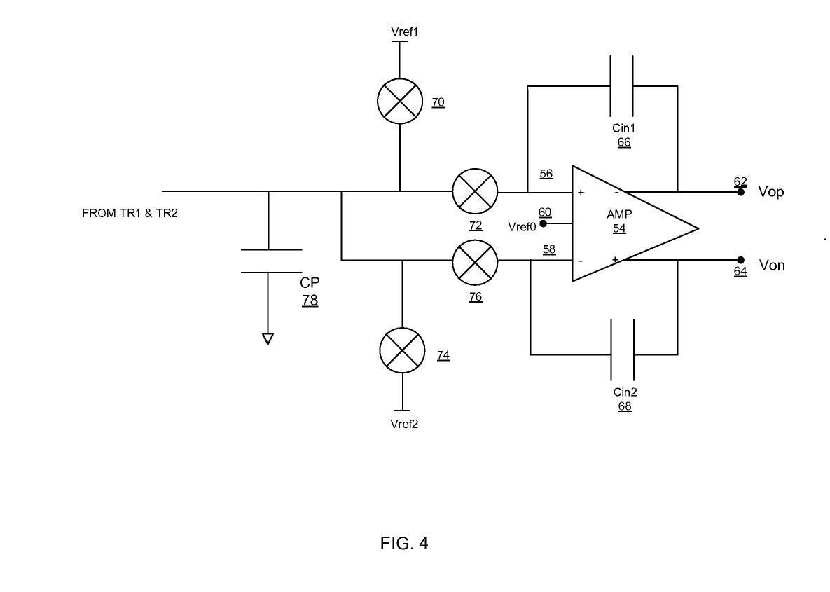

FIG. 3 illustrates one type of capacitance-to-voltage converter used as a capacitance detector 30. However, the present invention is not limited to the particular type of capacitance-to-voltage converter. Other capacitance-to-voltage converters also may be used to detect capacitance changes in the present invention. FIG. 4 illustrates a differential capacitance-to-voltage converter that may substitute the capacitance-to-voltage converter as shown in FIG. 3 according to an exemplary embodiment of the present invention. The differential capacitance-to-voltage converter may include a differential amplifier 54 that may include differential input nodes 56, 58, and differential output nodes 62, 64. In addition, the differential amplifier 54 also may include a common reference node 60. The differential capacitance-to-voltage converter also may include a first integrating capacitor Cin1 66 coupled between the input node 56 and the output node 62, and a second integrating capacitor Cin2 68 coupled between the input node 58 and the output node 64. Further, the differential capacitance-to-voltage converter may include four phased switches 70, 72, 74, 76. A first reference voltage Vref1 may be connected to the first input node 56 via serially-connected switches 70, 72, and a second reference voltage Vref2 may be connected to the second input node 58 via serially-connected switches 74, 76. Finally, the differential capacitance-to-voltage converter may include a capacitor CP 78 that may be at a first end coupled to ground and at a second end coupled to the input node 56 via the switch 72 and the input node 58 via the switch 74.

In operation, the four switches 70, 72, 74, 76 may operate in four phases with only one switch being engaged in one of the four phases. Thus, during phase one, switch 70 may be engaged (or closed) while switches 72, 74, 76 may be disengaged (or open); during phase two, switch 72 may be engaged (or closed) while switches 70, 74, 76 may be disengaged (or open); during phase three, switch 74 may be engaged (or closed) while switches 70, 72, 74 may be disengaged (or open); and during phase four, switch 78 may be engaged, switches 70, 72, 74 may be disengaged (or open). For convenience, the capacitive connection capacitor CC is omitted and only CTs is considered in the following discussion. During phase one, capacitor CP 78 and capacitors CTs of isolators (not shown) may be charged by the first reference voltage Vref1. Subsequently, during phase two, the charge Vref1 on CP and CTs may be applied to the input node 56. If the charge Vref1 is different from Vref0 at the common reference node, the amplifier 54 may generate a current charge of (Vref1−Vref0)*(CP+CTs) through the first integrating capacitor Cin1 66 to the output node 62. Similarly, during phase three, capacitor CP 78 and capacitors CTs of the isolators may be charged by the second reference voltage Vref2. Subsequently, during phase four, the charge Vref2 on CP and CTs may be applied to the input node 56. If the charge Vref2 is different from Vref0 at the common reference node, the amplifier 54 may generate a current charge of (Vref2−Vref0)*(CP+CTs) through the second integrating capacitor Cin2 68 to the output node 64. Since the first integrating capacitor Cin1 may be chosen to match the second integrating capacitor Cin2, the differential output Vop−Von may depend on the total charge current during the four phases, or (Vref1−Vref0)*(CP+CTs)−(Vref2−Vref0)*(CP+CTs)=(Vref1−Vref2)*(CP+CTs). In this way, the capacitance CTs of an isolation barrier may be reflected in the differential output of the different capacitance-to-voltage converter. Therefore, during normal operation when CTs does not change much, the differential output may keep stable pattern. However, in the event of breakdown of an isolator, the capacitance CTs may change significantly which may be reflected in an abnormal change in the differential output at the output nodes 62, 64.

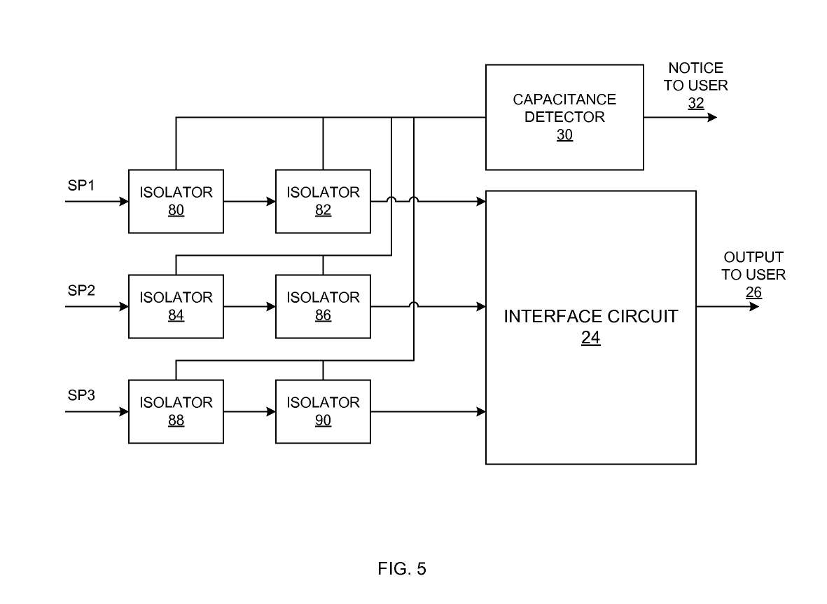

FIG. 3 illustrates an embodiment of sensing capacitance change in one signal path. In practice, there may be a number of signal paths between a drive circuit and an interface circuit. Each of the signal paths may include an isolator barrier that includes two or more isolators. It is possible that the capacitance of each of the isolator barrier may be monitored by a capacitance detector. However, it is also possible to use a single capacitance detector to monitor all of the signal paths. FIG. 5 illustrates a system that may detect isolator breakdowns in multiple signal paths according to an exemplary embodiment of the present invention. FIG. 5 illustrates a system that may include three signal paths, each of which may include a pair of isolators (80 to 90). These isolator pairs may be a transformer pair or a capacitor pair, but each pair may include a combined capacitance load. Thus, the first signal path (SP1) may include a load of CT1, the second signal path (SP2) may include a load of CT2, and the third signal path (SP3) may include a load of CT3. These capacitance loads CT1, CT2, CT3 may be coupled to the capacitor CP of the capacitance detector 30 to form a total capacitance load of (CP+CT1+CT2+CT3). Thus, during normal operation, CT1, CT2, CT3 may be stable and the output voltage of the capacitance detector 30 may maintain stable. However, in the event of an isolator breakdown among any of the three signal paths, the total capacitance load of (CP+CT1+CT2+CT3) may change. The change may be reflected in the output voltage of the capacitance detector 30. Based on this voltage change, a user may be notified for the breakdown of isolators and the potential breach of isolation barriers.

Those skilled in the art may appreciate from the foregoing description that the present invention may be implemented in a variety of forms, and that the various embodiments may be implemented alone or in combination. Therefore, while the embodiments of the present invention have been described in connection with particular examples thereof, the true scope of the embodiments and/or methods of the present invention should not be so limited since other modifications will become apparent to the skilled practitioner upon a study of the drawings, specification, and following claims.

What is claimed is:

1. A circuit system, comprising:
a first circuit for receiving an input signal;
a second circuit for interfacing with a user;
a signal path connecting the first circuit to the second circuit, the signal path including a first isolator and a second isolator serially connected to the first isolator; and
a capacitance detector that detects a change in a combined capacitance of the first and second isolators as an indicator of a breakdown of one of the first and second isolators.

2. The circuit system of claim 1, further comprising a status logic circuit that determines the breakdown of one of the first and second isolators based on the change in the combined capacitance of the first and second isolators.

3. The circuit system of claim 2, wherein the determining is based on a comparison of the change against a threshold value.

4. The circuit system of claim 2, wherein upon a determination of the breakdown of one of the first and second isolators, the status logic circuit notifies the user.

5. The circuit system of claim 1, wherein the first and second isolators are capacitors.

6. The circuit system of claim 5, wherein the first and second isolators have substantially identical capacitance.

7. The circuit system of claim 1, wherein the first and second isolators are transformers.

8. The circuit system of claim 7, wherein each of the transformers includes a top coil and a bottom coil, wherein the top coil includes a number of windings greater than or equal to a number of winding of the bottom coil, and wherein the bottom coil of a first transformer is coupled to the first circuit, the top coil of the first transformer is coupled to the top coil of a second transformer, and the bottom coil of the second transformer is capacitively coupled to the second circuit.

9. The circuit system of claim 7, wherein each of the transformers includes a parasitic capacitance.

10. The circuit system of claim 9, wherein the parasitic capacitance of a first transformer is substantially identical to the parasitic capacitance of a second transformer.

11. The circuit system of claim 1, wherein the capacitance detector includes a capacitance-to-voltage converter.

12. An isolation barrier that is coupled between a first circuit and a second circuit, comprising:
a first isolator; and
a second isolator that is serially connected to the first isolator,
wherein a capacitance detector is coupled to the serially-connected first and second isolators, and the capacitance detector detects a change in a combined capacitance of the first and second isolators as an indicator of a breakdown of one of the first and second isolators.

13. The isolation barrier of claim 12, wherein a status logic circuit is coupled to an output of the capacitor detector, and wherein the status logic circuit determines the breakdown of one of the first and second isolators based on the change in the combined capacitance of the first and second isolators.

14. The isolation barrier of claim 12, wherein the first and second isolators are capacitors that have substantially identical capacitance.

15. The isolation barrier of claim 12, wherein:
the first and second isolators are transformers;
each of the transformers includes a top coil and a bottom coil;
the top coil includes a number of windings greater than or equal to a number of winding of the bottom coil; and
the bottom coil of a first transformer is coupled to the first circuit, the top coil of the first transformer is coupled to the top coil of a second transformer, and the bottom coil of the second transformer is capacitively coupled to the second circuit.

16. The isolation barrier of claim 15, wherein each of the transformers has a substantially identical parasitic capacitance.

17. The isolation barrier of claim 12, wherein the capacitance detector includes a capacitance-to-voltage converter.

18. A method of detecting a potential breakdown in an isolation barrier between a first circuit and a second circuit, comprising:
providing a first isolator and a second isolator in the isolation barrier;
serially connecting the first isolator and the second isolator; and
providing a capacitance detector that detects a change in a combined capacitance of the first and second isolators as an indicator of a breakdown of one of the first and second isolators.

19. The method of claim 18, wherein the first and second isolators are capacitors that have substantially identical capacitance.

20. The method of claim 18, wherein the first and second isolators are transformers that have substantially identical parasitic capacitance.
